(19) United States
(12) Patent Application Publication
(10) Pub. No.: US 2025/0167189 A1
(43) Pub. Date: May 22, 2025

(54) DISPLAY DEVICE INCLUDING PLASTICALLY DEFORMABLE METAL PATTERN

(71) Applicant: SAMSUNG ELECTRONICS CO., LTD., Suwon-si (KR)

(72) Inventors: Jae-Min JUNG, Suwon-si (KR); Seung Hyun Cho, Suwon-si (KR)

(73) Assignee: SAMSUNG ELECTRONICS CO., LTD., Suwon-si (KR)

(21) Appl. No.: 18/888,923

(22) Filed: Sep. 18, 2024

(30) Foreign Application Priority Data
Nov. 20, 2023 (KR) 10-2023-0160773

(51) Int. Cl. H01L 33/62

(52) U.S. Cl. CPC H01L 25/167; H01L 25/0753; H10K 59/95

(57) ABSTRACT

A display device including: a thin film substrate; a display substrate connected to a first side of the thin film substrate; a light emitting element layer on an upper surface of the display substrate; a circuit board connected to a second side of the thin film substrate opposite the first side of the thin film substrate in a first horizontal direction; a metal pattern on the thin film substrate, wherein the metal pattern does not overlap a first portion of the thin film substrate connected to the display substrate and does not overlap a second portion of the thin film substrate connected to the circuit board in a vertical direction, wherein the metal pattern includes a metal, and wherein the metal pattern is electrically insulated from the thin film substrate; and a pattern region, wherein the metal pattern is around the pattern region.

### CROSS-REFERENCE TO RELATED APPLICATION

This application is based on and claims priority under 35 U.S.C. § 119 to Korean Patent Application No. 10-2023-0160773 filed on Nov. 20, 2023 in the Korean Intellectual Property Office, the disclosure of which is incorporated by reference herein in its entirety.

### BACKGROUND

### 1. Field

The present disclosure relates to a display device, and more particularly to a display device including plastically deformable metal pattern.

### 2. Description of Related Art

Display devices may be used for displaying images various forms. Some examples of a display device may include a flat panel display device such as a liquid crystal display, a field emission display and a light emitting display. A light emitting display device may include an organic light emitting display device including an organic light emitting diode element as a light emitting element, an inorganic light emitting display device including an inorganic semiconductor element as a light emitting element, or a subminiature light emitting diode element (which may be referred to as micro light emitting diode element) as a light emitting element.

Some light emitting display devices may be included in a head mounted display (HMD), which may refer to a glasses-type monitor device of a virtual reality (VR) or augmented reality (AR), which may be worn by the user in the form of glasses or a helmet and in which a focal point is formed at a close distance to the eyes.

### SUMMARY

Provided is a display device that stably connects a display panel and a circuit board by disposing a metal pattern that is plastically deformable on a surface of a thin film substrate.

Additional aspects will be set forth in part in the description which follows and, in part, will be apparent from the description, or may be learned by practice of the presented embodiments.

In accordance with an aspect of the disclosure, a display device includes: a thin film substrate; a display substrate connected to a first side of the thin film substrate; a light emitting element layer on an upper surface of the display substrate; a circuit board connected to a second side of the thin film substrate opposite the first side of the thin film substrate in a first horizontal direction; a metal pattern on the thin film substrate, wherein the metal pattern does not overlap a first portion of the thin film substrate connected to the display substrate and does not overlap a second portion of the thin film substrate connected to the circuit board in a vertical direction, wherein the metal pattern includes a metal, and wherein the metal pattern is electrically insulated from the thin film substrate; and a pattern region, wherein the metal pattern is around the pattern region.

In accordance with an aspect of the disclosure, a display device includes: a thin film substrate; a display substrate connected to a first side of the thin film substrate; a light emitting element layer on an upper surface of the display substrate; a semiconductor chip on a lower surface of the thin film substrate; a metal pattern disposed on the thin film substrate, wherein the metal pattern is spaced apart from the semiconductor chip in a first horizontal direction, wherein the metal pattern does not overlap a portion of the thin film substrate connected to the display substrate in a vertical direction, wherein the metal pattern includes a metal, and wherein the metal pattern is electrically insulated from the thin film substrate; a pattern region, wherein the metal pattern is around the pattern region; and a passivation layer on a surface of the metal pattern, wherein the passivation layer is disposed on a surface of the thin film substrate exposed to the pattern region, and wherein the passivation layer includes an insulating material.

In accordance with an aspect of the disclosure, a display device includes: a thin film substrate;
a display substrate connected to a first side of the thin film substrate; a light emitting element layer disposed on an upper surface of the display substrate; a circuit board connected to a second side of the thin film substrate opposite the first side of the thin film substrate in a first horizontal direction; a semiconductor chip on a lower surface of the thin film substrate; a metal pattern on the lower surface of the thin film substrate, wherein the metal pattern is spaced apart from the semiconductor chip in the first horizontal direction, wherein the metal pattern does not overlap a first portion of the thin film substrate connected to the display substrate and does not overlap a second portion of the thin film substrate connected to the circuit board in a vertical direction, wherein the metal pattern includes a metal, and wherein the metal pattern is electrically insulated from the thin film substrate; a pattern region on the lower surface of the thin film substrate, wherein the metal pattern is around the pattern region; and a passivation layer on a surface of the metal pattern, wherein the passivation layer is on the lower surface of the thin film substrate exposed to the pattern region, wherein the passivation layer is not disposed on a surface of the semiconductor chip, and wherein the passivation layer does not include an insulating material.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a plan view for explaining a display device according to some embodiments of the present disclosure;

FIG. 2 is a cross-sectional view taken along a line A-A′ of FIG. 1;

FIG. 3 is a plan view for explaining a structure formed on a thin film substrate of the display device according to some embodiments of the present disclosure;

FIG. 4 is a cross-sectional view taken along a line B-B′ of FIG. 3;

FIGS. 5 to 8 are intermediate step diagrams for explaining a method for fabricating a display device according to some embodiments of the present disclosure;

FIG. 9 is a plan view for explaining a display device according to some embodiments of the present disclosure;

FIG. 10 is a plan view for explaining a display device according to some embodiments of the present disclosure;

FIG. 11 is a cross-sectional view for explaining a display device according to some embodiments of the present disclosure;

FIG. 12 is a cross-sectional view for explaining a display device according to some embodiments of the present disclosure; and

FIG. 13 is a cross-sectional view for explaining a display device according to some embodiments of the present disclosure.

### DETAILED DESCRIPTION OF THE EMBODIMENTS

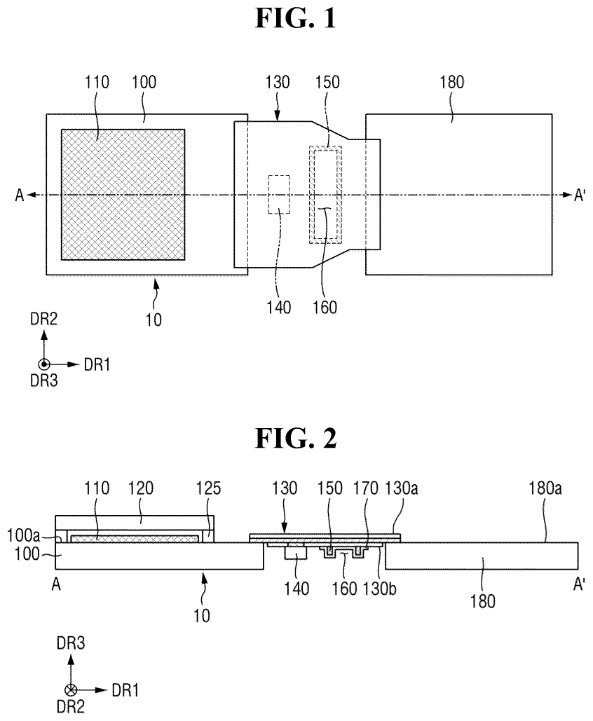

Hereinafter, a display device according to some embodiments of the present disclosure is described with reference to FIGS. 1 to 4.

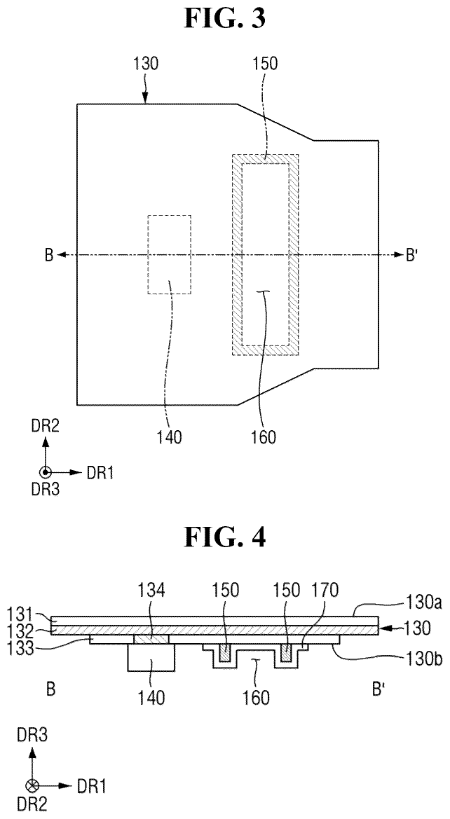

FIG. 1 is a plan view for explaining the display device according to some embodiments of the present disclosure. FIG. 2 is a cross-sectional view taken along a line A-A′ of FIG. 1. FIG. 3 is a plan view for explaining a structure formed on a thin film substrate of the display device according to some embodiments of the present disclosure. FIG. 4 is a cross-sectional view taken along a line B-B′ of FIG. 3.

Referring to FIGS. 1 to 4, the display device according to some embodiments of the present disclosure may include a display panel 10, a thin film substrate 130, a semiconductor chip 140, a metal pattern 150, a pattern region 160, a passivation layer 170, and a circuit board 180.

The display panel 10 may include a display substrate 100, a light emitting element layer 110, an upper substrate 120, and a partition 125. The display substrate 100 may include, for example, silicon (Si). For example, the display substrate 100 may be a silicon substrate.

The light emitting element layer 110 may be disposed on an upper surface 100a of the display substrate 100. The light emitting element layer 110 may include a plurality of light emitting elements. For example, each of the plurality of light emitting elements may be a micro light emitting diode or an organic light emitting diode. The partition 125 may be disposed on the upper surface 100a of the display substrate 100. The partition 125 may surround a side wall of the light emitting element layer 110. For example, the partition 125 may include silicon (Si). For example, the partition 125 may include a silicon single crystal layer, but embodiments are not limited thereto.

The upper substrate 120 may be disposed on the upper surface 100a of the display substrate 100. For example, the upper substrate 120 may be disposed on each of the upper surface of the light emitting element layer 110 and the upper surface of the partition 125. For example, the light emitting element layer 110 may be covered with the upper substrate 120 and the partition 125. For example, the upper substrate 120 may include a transparent substrate such as a sapphire substrate (Al₂O₃) or glass. However, embodiments are not limited thereto. In some embodiments, the upper substrate 120 may include a conductive substrate such as GaN, SiC, ZnO, Si, GaP, and GaAs.

The thin film substrate 130 may be connected to the display substrate 100. For example, the display substrate 100 may be connected to a first side of the thin film substrate 130. For example, a lower surface of the first side of the thin film substrate 130 may be connected to an edge region of the upper surface 100a of the display substrate 100. The thin film substrate 130 may be a flexible film, for example, such as a chip-on-film (COF).

Hereinafter, each of a first horizontal direction DR1 and a second horizontal direction DR2 may be a direction parallel to the upper surface 130a of the thin film substrate 130. The second horizontal direction DR2 may be a direction perpendicular to the first horizontal direction DR1. A vertical direction DR3 may be a direction perpendicular to each of the first horizontal direction DR1 and the second horizontal direction DR2. For example, the vertical direction DR3 may be a direction perpendicular to the upper surface 130a of the thin film substrate 130.

The thin film substrate 130 may include a base film 131, a wiring layer 132, an insulating layer 133, and a connecting terminal 134. The base film 131 may include an insulating material. For example, the base film 131 may include polyimide. The wiring layer 132 may be disposed on the lower surface of the base film 131. The wiring layer 132 may include a conductive material. For example, the wiring layer 132 may include copper (Cu). The wiring layer 132 may electrically connect the display substrate 100 with the circuit board 180.

The insulating layer 133 may be formed on the lower surface of the wiring layer 132. For example, a width of the insulating layer 133 in the first horizontal direction DR1 may be smaller than a width of the base film 131 in the first horizontal direction DR1. For example, the insulating layer 133 may be not disposed on the portion of the wiring layer 132 connected to each of the display substrate 100 and the circuit board 180. For example, each of the display substrate 100 and the circuit board 180 may be connected to a portion the wiring layer 132 of a portion on which the insulating layer 133 is not disposed. The insulating layer 133 may include an insulating material. The connecting terminal 134 may be disposed inside the insulating layer 133. The connecting terminal 134 may include a conductive material. The connecting terminal 134 may be electrically connected to the wiring layer 132.

The circuit board 180 may be connected to a second side of the thin film substrate 130 that is opposite to the first side of the thin film substrate 130 in the first horizontal direction DR1. For example, the lower surface of the second side of the thin film substrate 130 may be connected to the upper surface 180a of the circuit board 180. For example, the circuit board 180 may be a flexible printed circuit board (FPCB), a printed circuit board (PCB) or a flexible printed circuit (FPC).

The semiconductor chip 140 may be disposed on the lower surface 130b of the thin film substrate 130. For example, the semiconductor chip 140 may be disposed on the lower surface of each of the insulating layer 133 and the connecting terminal 134. The semiconductor chip 140 may be electrically connected to the connecting terminal 134. For example, the semiconductor chip 140 may be electrically connected to the wiring layer 132 through the connecting terminal 134.

For example, the semiconductor chip 140 may be not disposed on a portion of the thin film substrate 130 connected to the display substrate 100. For example, the semiconductor chip 140 may not overlap a part of the thin film substrate 130 connected to the display substrate 100 in the vertical direction DR3. Furthermore, the semiconductor chip 140 may be not disposed on a part of the thin film substrate 130 connected to the circuit board 180. For example, the semiconductor chip 140 may not overlap a part of the thin film substrate 130 connected to the circuit board 180 in the vertical direction DR3.

For example, the semiconductor chip 140 may include a display driver integrated circuit (DSDI) or a timing controller (TCON). However, embodiments are not limited thereto. For example, in some embodiments, the semiconductor chip 140 may include a connector or a memory semiconductor chip.

The metal pattern 150 may be disposed on the lower surface 130b of the thin film substrate 130. For example, the metal pattern 150 may be disposed on the lower surface of insulating layer 133. For example, the upper surface of the metal pattern 150 may abut the lower surface of the insulating layer 133. The metal pattern 150 may protrude from the lower surface 130b of the thin film substrate 130. For example, the metal pattern 150 may be spaced apart from the semiconductor chip 140 in the first horizontal direction DR1. For example, the metal pattern 150 may be not disposed on a part of the thin film substrate 130 connected to the display substrate 100. For example, the metal pattern 150 may not overlap a part of the thin film substrate 130 connected to the display substrate 100 in the vertical direction DR3. Furthermore, the metal pattern 150 may be not disposed on a part of the thin film substrate 130 connected to the circuit board 180. For example, the metal pattern 150 may not overlap a part of the thin film substrate 130 connected to the circuit board 180 in the vertical direction DR3.

In embodiments, in a plane defined by the first and second horizontal directions DR1 and DR2, the metal pattern 150 may have a linear shape. For example, in the plane defined by the first and second horizontal directions DR1 and DR2, the metal pattern 150 may have a linear shape disposed along one or more edges of a rectangle. However, embodiments are not limited thereto. In other embodiments, in the plane defined by the first and second horizontal directions DR1 and DR2, the metal pattern 150 may have a linear shape disposed along one or more edges of a polygon. In some embodiments, the metal pattern 150 may have a linear shape disposed along one or more edges of a curved surface in a plane defined by the first and second horizontal directions DR1 and DR2. For example, the metal pattern 150 may be integrally formed.

For example, the lower surface of the metal pattern 150 may be formed to be higher than the lower surface of the semiconductor chip 140. For example, the lower surface of the metal pattern 150 may be formed to be closer to the lower surface 130b of the thin film substrate 130 than the lower surface of the semiconductor chip 140. For example, the height of the metal pattern 150 in the vertical direction DR3 may be in a range of 50 micrometers (μm) to 200 μm. Here, the height of the metal pattern 150 in the vertical direction DR3 may be referred to as a height in the vertical direction DR3 from the upper surface of the metal pattern 150 abutting the lower surface 130b of the thin film substrate 130 to the lower surface of the metal pattern 150.

The metal pattern 150 may include a metal. For example, the metal pattern 150 may include at least one of aluminum (Al), copper (Cu), gold (Au), silver (Ag) or iron (Fe). For example, the metal pattern 150 may be electrically insulated from the thin film substrate 130. For example, the metal pattern 150 may be electrically insulated from the wiring layer 132.

The pattern region 160 may be formed on the lower surface 130b of the thin film substrate 130. For example, the pattern region 160 may be formed on the lower surface of insulating layer 133. The pattern region 160 may be a region surrounded by the metal pattern 150. For example, the side walls of the pattern region 160 may be defined by the metal pattern 150. Further, the upper surface of the pattern region 160 may be defined by the lower surface 130b of the thin film substrate 130. For example, in the plane defined by the first and second horizontal directions DR1 and DR2, the side walls of the pattern region 160 may be completely surrounded by the metal pattern 150.

The passivation layer 170 may be disposed on the lower surface 130b of the thin film substrate 130. For example, the passivation layer 170 may be disposed on the lower surface of the insulating layer 133. The passivation layer 170 may cover the surface of the metal pattern 150. For example, the passivation layer 170 may be disposed on the side walls and lower surface of the metal pattern 150. Additionally, the passivation layer 170 may be disposed on the lower surface 130b of the thin film substrate 130 exposed to the pattern region 160. For example, the passivation layer 170 may be disposed on the lower surface of the insulating layer 133 exposed to the pattern region 160. The passivation layer 170 may be disposed on the lower surface 130b of the thin film substrate 130 adjacent to the metal pattern 150. For example, the passivation layer 170 may abut each of the lower surface 130b of the thin film substrate 130, and the side wall and lower surface of the metal pattern 150. For example, the passivation layer 170 may abut the lower surface of the insulating layer 133.

For example, the passivation layer 170 may be not disposed on the surface of the semiconductor chip 140. For example, the passivation layer 170 may be not disposed on the side walls and the lower surface of the semiconductor chip 140. For example, the passivation layer 170 may not abut on the semiconductor chip 140. For example, the passivation layer 170 may be formed conformally. For example, the passivation layer 170 may be formed to have a uniform thickness.

The passivation layer 170 may include an insulating material. For example, passivation layer 170 may include polyimide. In some embodiments, the passivation layer 170 may include at least one material from among phenolic resin, epoxy resin, FR-4, tetrafunctional epoxy, polyphenylene ether, epoxy/polyphenylene oxide, BT (bismaleimide triazine), thermount, cyanate ester, and liquid crystal polymer.

In the display device according to some embodiments of the present disclosure, a metal pattern 150 including a metal may be disposed on the lower surface 130b of the thin film substrate 130. The thin film substrate 130 including the metal pattern 150 may be easily bent, and may maintain a bent state after being bent. For example, the metal pattern 150 may experience plastic deformation. For example, the display device according to some embodiments of the present disclosure may stably connect the display panel 10 and the circuit board 180, by disposing the plastically deformable metal pattern 150 on the surface of the thin film substrate 130.

Hereinafter, a method for fabricating the display device according to some embodiments of the present disclosure is described with reference to FIGS. 2 and 5 to 8.

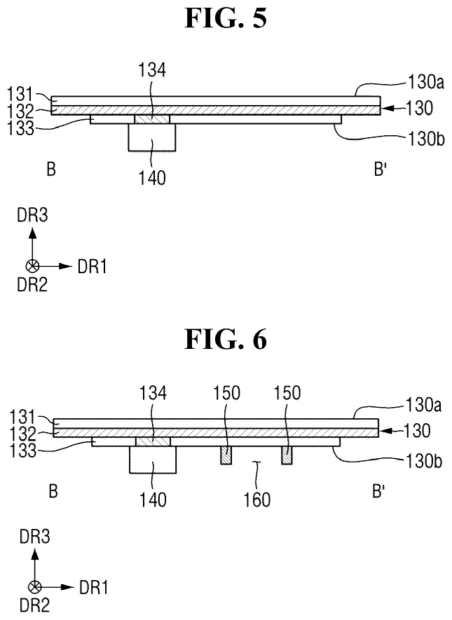

FIGS. 5 to 8 are intermediate step diagrams for explaining the method for fabricating the display device according to some embodiments of the present disclosure.

Referring to FIG. 5, the thin film substrate 130 including the base film 131, the wiring layer 132, the insulating layer 133, and the connecting terminal 134 may be provided. Subsequently, the semiconductor chip 140 may be mounted on the lower surface 130b of the thin film substrate 130. For example, the semiconductor chip 140 may be mounted on the lower surface of the insulating layer 133.

Referring to FIG. 6, the metal pattern 150 may be formed on the lower surface 130b of the thin film substrate 130. For example, the metal pattern 150 may be formed on the lower surface of the insulating layer 133. For example, as shown in FIG. 3, in the plane defined by the first and second horizontal directions DR1 and DR2, the metal pattern 150 may have a linear line disposed along the edge of a rectangle. The pattern region 160 may be formed on the lower surface 130b of the thin film substrate 130. For example, the pattern region 160 may be formed on the lower surface of the insulating layer 133. The pattern region 160 may be a region surrounded by metal pattern 150.

For example, the lower surface of the metal pattern 150 may be formed to be higher than the lower surface of the semiconductor chip 140. For example, the lower surface of the metal pattern 150 may be formed to be closer to the lower surface 130b of the thin film substrate 130 than the lower surface of the semiconductor chip 140.

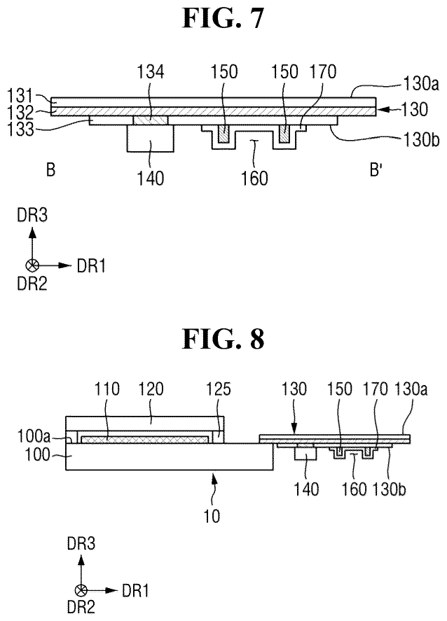

Referring to FIG. 7, the passivation layer 170 may be formed on the lower surface 130b of the thin film substrate 130. For example, the passivation layer 170 may be formed on the lower surface of the insulating layer 133. The passivation layer 170 may cover the surfaces of the metal pattern 150 and the pattern region 160 on the lower surface 130b of the thin film substrate 130. Furthermore, the passivation layer 170 may also be formed on the lower surface 130b of the thin film substrate 130 adjacent to the metal pattern 150. For example, the passivation layer 170 may be spaced apart from the semiconductor chip 140 in the first horizontal direction DR1. For example, the passivation layer 170 may be formed by attaching a film having a uniform thickness onto the metal pattern 150 and the pattern region 160. Accordingly, the passivation layer 170 may have a uniform thickness.

Referring to FIG. 8, the display panel 10 including the display substrate 100, the light emitting element layer 110, the upper substrate 120, and the partition 125 may be provided. Subsequently, the lower surface of the first side of the thin film substrate 130 may be connected to the edge region of the upper surface 100a of the display substrate 100. For example, the lower surface of the wiring layer 132 disposed on the first side of the thin film substrate 130 may be connected to the edge region of the upper surface 100a of the display substrate 100.

Referring again to FIG. 2, a circuit board 180 may be connected to a lower surface of the second side of the thin film substrate 130 opposite to the first side of the thin film substrate 130 in the first horizontal direction DR1. For example, the circuit board 180 may be connected to the lower surface of the wiring layer 132 disposed on the second side of the thin film substrate 130. The display device shown in FIG. 2 may be fabricated using such a fabricating process.

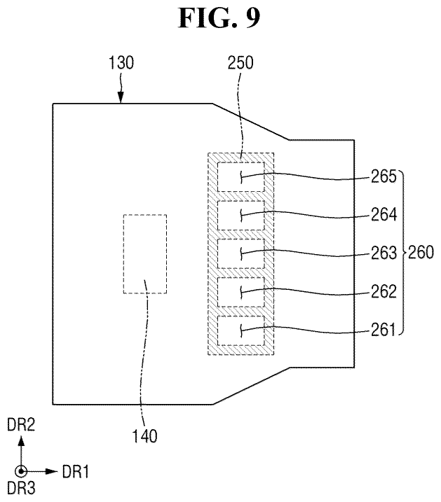

Hereinafter, a display device according to some embodiments of the present disclosure is described with reference to FIG. 9. The following description may mainly focus on the differences from the display device shown in FIGS. 1 to 4.

FIG. 9 is a plan view for explaining a display device according to some embodiments of the present disclosure.

Referring to FIG. 9, in the display device according to some embodiments of the present disclosure, a pattern region may include a plurality of sub-pattern regions 260, for example first sub-pattern region 261, second sub-pattern region 262, third sub-pattern region 263, fourth sub-pattern region 264, and fifth sub-pattern region 265.

For example, the plurality of sub-pattern regions 260 spaced apart from each other in the second horizontal direction DR2. For example, the first to fifth sub-pattern regions 261, 262, 263, 264, and 265 may be sequentially spaced apart in the second horizontal direction DR2. For example, in a plane defined by the first and second horizontal directions DR1 and DR2, each of the first to fifth sub-pattern regions 261, 262, 263, 264, and 265 may have a rectangular shape. However, the planar shape of each of the first to fifth sub-pattern regions 261, 262, 263, 264, and 265 is not limited. Although five sub-pattern regions 260 are illustrated in FIG. 9, this is merely an example, and the number of the sub-pattern regions 260 is not limited thereto.

The metal pattern 250 may surround each of the first to fifth sub-pattern regions 261, 262, 263, 264, and 265. For example, in the plane defined by the first and second horizontal directions DR1 and DR2, the metal pattern 250 may surround the side walls of each of the first to fifth sub-pattern regions 261, 262, 263, 264, and 265. For example, the metal pattern 250 may be integrally formed.

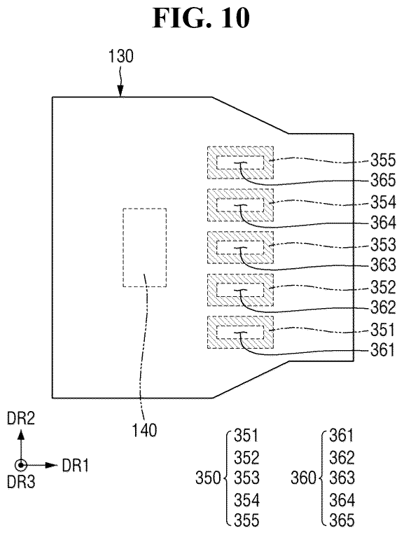

Hereinafter, a display device according to some embodiments of the present disclosure is described with reference to FIG. 10. The following description may focus mainly on the differences from the display device shown in FIGS. 1 to 4.

FIG. 10 is a plan view for explaining a display device according to some embodiments of the present disclosure.

Referring to FIG. 10, in the display device according to some embodiments of the present disclosure, the pattern region may include a plurality of sub-pattern regions 360, for example first sub-pattern region 361, second sub-pattern region 362, third sub-pattern region 363, fourth sub-pattern region 364, and fifth sub-pattern region 365, and the metal pattern may include a plurality of metal sub-patterns 350, for example first metal sub-pattern 351, second metal sub-pattern 352, third metal sub-pattern 353, fourth metal sub-pattern 354, and fifth metal sub-pattern 355.

For example, the pattern region may include a plurality of sub-pattern regions 360 spaced apart from each other in the second horizontal direction DR2. For example, the first to fifth sub-pattern regions 361, 362, 363, 364, and 365 may be sequentially spaced apart in the second horizontal direction DR2. For example, in the plane defined by the first and second horizontal directions DR1 and DR2, each of the first to fifth sub-pattern regions 361, 362, 363, 364, and 365 may have a rectangular shape. However, the planar shape of each of the first to fifth sub-pattern regions 361, 362, 363, 364, and 365 is not limited thereto. Although five sub-pattern regions 361, 362, 363, 364, and 365 are illustrated in FIG. 10, this is merely an example, and the number of the sub-pattern regions 360 is not limited thereto.

For example, the metal pattern may include a plurality of metal sub-patterns 350 spaced apart from each other in the second horizontal direction DR2. For example, the plurality of metal sub-patterns 351, 352, 353, 354, and 355 may be disposed at positions corresponding to the plurality of sub-pattern regions 361, 362, 363, 364, and 365. For example, the first to fifth metal sub-patterns 351, 352, 353, 354, and 355 may be sequentially spaced apart in the second horizontal direction DR2.

For example, in the plane defined by the first and second horizontal directions DR1 and DR2, each of the first to fifth metal sub-patterns 351, 352, 353, 354, and 355 may have a linear shape disposed along the edge of a rectangle. In the plane defined by the first and second horizontal directions DR1 and DR2, each of the first to fifth metal sub-patterns 351, 352, 353, 354, and 355 may surround the side walls of each of the first to fifth sub-pattern regions 361, 362, 363, 364, and 365. For example, each of the first to fifth sub-pattern regions 361, 362, 363, 364, and 365 may be integrally formed.

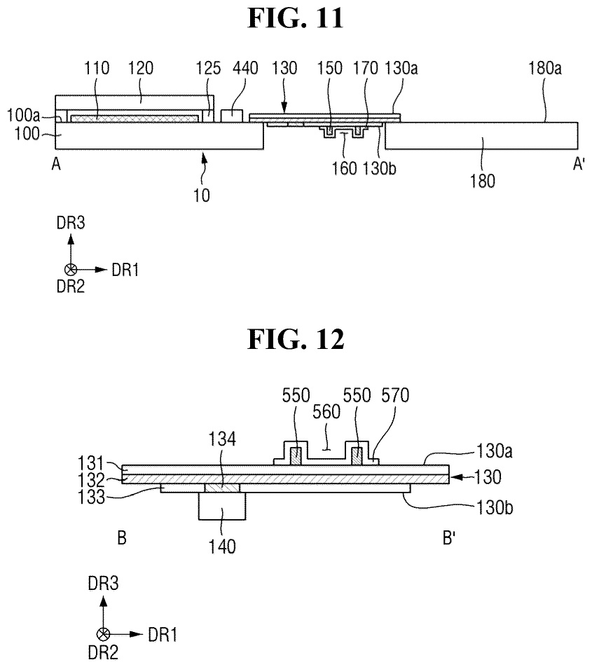

Hereinafter, a display device according to some embodiments of the present disclosure is described with reference to FIG. 11. The following description may mainly focus on the differences from the display device shown in FIGS. 1 to 4.

FIG. 11 is a cross-sectional view for explaining a display device according to some embodiments of the present disclosure.

Referring to FIG. 11, in the display device according to some embodiments of the present disclosure, a semiconductor chip 440 may be disposed on the upper surface 100a of the display substrate 100.

For example, the semiconductor chip 440 may be disposed on the upper surface 100a of the display substrate 100 between the partition 125 and the thin film substrate 130. For example, no other semiconductor chip may be disposed on the lower surface 130b of the thin film substrate 130. However, embodiments are not limited thereto. In some embodiments, the semiconductor chip 440 disposed on the upper surface 100a of the display substrate 100 may include a display driver integrated circuit (DDI) or a timing controller (TCON), and a connector or a memory semiconductor chip may be disposed on the lower surface 130b of the thin film substrate 130.

Hereinafter, a display device according to some embodiments of the present disclosure is described with reference to FIG. 12. The following description may mainly focus on the differences from the display device shown in FIGS. 1 to 4.

FIG. 12 is a cross-sectional view for explaining a display device according to some embodiments of the present disclosure.

Referring to FIG. 12, in the display device according to some embodiments of the present disclosure, a metal pattern 550 may be disposed on the upper surface 130a of the thin film substrate 130.

For example, the metal pattern 550 may protrude from the upper surface 130a of the thin film substrate 130. The pattern region 560 may be formed on the upper surface 130a of the thin film substrate 130. The pattern region 560 may be a region surrounded by metal pattern 550. For example, the side walls of the pattern region 560 may be defined by the metal pattern 550. For example, each of the metal pattern 550 and the pattern region 560 may not overlap the semiconductor chip 140 in the vertical direction DR3.

For example, a passivation layer 570 may be disposed on the upper surface 130a of the thin film substrate 130. The passivation layer 570 may cover the surface of the metal pattern 550. For example, the passivation layer 570 may be disposed on the side walls and upper surface of the metal pattern 550. Additionally, the passivation layer 570 may be disposed on the upper surface 130a of the thin film substrate 130 exposed to the pattern region 560. The passivation layer 570 may be disposed on the upper surface 130a of the thin film substrate 130 adjacent to the metal pattern 550. For example, the passivation layer 570 may abut on each of the upper surface 130a of the thin film substrate 130, and the side wall and upper surface of the metal pattern 550.

For example, the passivation layer 570 may not overlap the semiconductor chip 140 in the vertical direction DR3. However, embodiments are not limited thereto. In some embodiments, at least a part of the passivation layer 570 may overlap the semiconductor chip 140 in the vertical direction DR3.

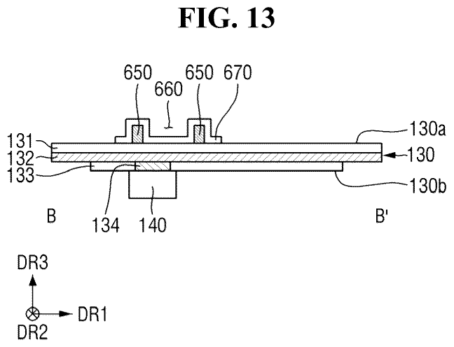

Hereinafter, a display device according to some embodiments of the present disclosure is described with reference to FIG. 13. The following description may mainly focus on the differences from the display device shown in FIGS. 1 to 4.

FIG. 13 is a cross-sectional view for explaining the display device according to some embodiments of the present disclosure.

Referring to FIG. 13, in the display device according to some embodiments of the present disclosure, a metal pattern 650 may be disposed on the upper surface 130a of the thin film substrate 130.

For example, the metal pattern 650 may be disposed to protrude from the upper surface 130a of the thin film substrate 130. A pattern region 660 may be formed on the upper surface 130a of the thin film substrate 130. The pattern region 660 may be a region surrounded by the metal pattern 650. For example, the side walls of the pattern region 660 may be defined by the metal pattern 650. For example, each of the metal pattern 650 and the pattern region 660 may overlap the semiconductor chip 140 in the vertical direction DR3.

For example, a passivation layer 670 may be disposed on the upper surface 130a of the thin film substrate 130. The passivation layer 670 may cover the surface of the metal pattern 650. For example, the passivation layer 670 may be disposed on the side walls and upper surface of the metal pattern 650. Additionally, the passivation layer 670 may be disposed on the upper surface 130a of the thin film substrate 130 exposed to the pattern region 660. The passivation layer 670 may be disposed on the upper surface 130a of the thin film substrate 130 adjacent to the metal pattern 650. For example, the passivation layer 670 may abut on each of the upper surface 130a of the thin film substrate 130, and the side wall and upper surface of the metal pattern 650. For example, the passivation layer 670 may overlap the semiconductor chip 140 in the vertical direction DR3.

Although some embodiments according to the present disclosure are described above with reference to the accompanying drawings, embodiments are not limited to the embodiments described above, and may be fabricated in various different forms. Those skilled in the art will appreciate that the present disclosure may be embodied in other specific forms without changing the technical spirit or features of the present disclosure. Accordingly, the above-described embodiments should be understood in all respects.

What is claimed is:

1. A display device comprising:
a thin film substrate;
a display substrate connected to a first side of the thin film substrate;
a light emitting element layer on an upper surface of the display substrate;
a circuit board connected to a second side of the thin film substrate opposite the first side of the thin film substrate in a first horizontal direction;
a metal pattern on the thin film substrate, wherein the metal pattern does not overlap a first portion of the thin film substrate connected to the display substrate and does not overlap a second portion of the thin film substrate connected to the circuit board in a vertical direction, wherein the metal pattern comprises a metal, and wherein the metal pattern is electrically insulated from the thin film substrate; and
a pattern region, wherein the metal pattern is around the pattern region.

2. The display device of claim 1, further comprising a passivation layer on a surface of the metal pattern,
wherein the passivation layer is on a surface of the thin film substrate exposed to the pattern region, and
wherein the passivation layer comprises an insulating material.

3. The display device of claim 2, wherein the passivation layer has a uniform thickness.

4. The display device of claim 1, wherein a height of the metal pattern in the vertical direction is in a range of 50 μm to 200 μm.

5. The display device of claim 1, further comprising a semiconductor chip on a lower surface of the thin film substrate,
wherein the semiconductor chip is spaced apart from the metal pattern.

6. The display device of claim 5, wherein the metal pattern is on the lower surface of the thin film substrate.

7. The display device of claim 5, wherein the metal pattern is on an upper surface of the thin film substrate.

8. The display device of claim 7, wherein the metal pattern does not overlap the thin film substrate in the vertical direction.

9. The display device of claim 7, wherein the metal pattern overlaps the thin film substrate in the vertical direction.

10. The display device of claim 1, further comprising a semiconductor chip on the upper surface of the display substrate.

11. The display device of claim 1, wherein the pattern region comprises a plurality of sub-pattern regions spaced apart from each other in a second horizontal direction perpendicular to the first horizontal direction, and
wherein the metal pattern is around each sub-pattern region from among the plurality of sub-pattern regions.

12. The display device of claim 11, wherein the metal pattern comprises a plurality of metal sub-patterns spaced apart from each other in the second horizontal direction, and
wherein each metal sub-pattern from among the plurality of metal sub-patterns is around a corresponding sub-pattern region from among the plurality of sub-pattern regions.

13. A display device comprising:
a thin film substrate;
a display substrate connected to a first side of the thin film substrate;
a light emitting element layer on an upper surface of the display substrate;
a semiconductor chip on a lower surface of the thin film substrate;
a metal pattern disposed on the thin film substrate, wherein the metal pattern is spaced apart from the semiconductor chip in a first horizontal direction, wherein the metal pattern does not overlap a portion of the thin film substrate connected to the display substrate in a vertical direction, wherein the metal pattern comprises a metal, and wherein the metal pattern is electrically insulated from the thin film substrate;
a pattern region, wherein the metal pattern is around the pattern region; and
a passivation layer on a surface of the metal pattern, wherein the passivation layer is disposed on a surface of the thin film substrate exposed to the pattern region, and wherein the passivation layer comprises an insulating material.

14. The display device of claim 13, further comprising a circuit board connected to a second side of the thin film substrate opposite the first side of the thin film substrate in the first horizontal direction,
wherein the circuit board does not overlap the metal pattern in the vertical direction.

15. The display device of claim 13, wherein the passivation layer is not on a surface of the semiconductor chip.

16. The display device of claim 13, wherein a lower surface of the metal pattern is closer to the surface of the thin film substrate than a lower surface of the semiconductor chip.

17. The display device of claim 13, wherein the metal pattern is on the lower surface of the thin film substrate.

18. The display device of claim 13, wherein the metal pattern is on an upper surface of the thin film substrate.

19. The display device of claim 13, wherein the pattern region comprises a plurality of sub-pattern regions spaced from each other in a second horizontal direction perpendicular to the first horizontal direction, and
wherein the metal pattern is around each sub-pattern region from among the plurality of sub-pattern regions.

20. A display device comprising:
a thin film substrate;
a display substrate connected to a first side of the thin film substrate;
a light emitting element layer disposed on an upper surface of the display substrate;
a circuit board connected to a second side of the thin film substrate opposite the first side of the thin film substrate in a first horizontal direction;
a semiconductor chip on a lower surface of the thin film substrate;
a metal pattern on the lower surface of the thin film substrate, wherein the metal pattern is spaced apart from the semiconductor chip in the first horizontal direction, wherein the metal pattern does not overlap a first portion of the thin film substrate connected to the display substrate and does not overlap a second portion of the thin film substrate connected to the circuit board in a vertical direction, wherein the metal pattern comprises a metal, and wherein the metal pattern is electrically insulated from the thin film substrate;
a pattern region on the lower surface of the thin film substrate, wherein the metal pattern is around the pattern region; and
a passivation layer on a surface of the metal pattern, wherein the passivation layer is on the lower surface of the thin film substrate exposed to the pattern region, wherein the passivation layer is not disposed on a surface of the semiconductor chip, and wherein the passivation layer does not include an insulating material.
